(19) United States
(12) Patent Application Publication
(10) Pub. No.: US 2006/0152232 A1
(43) Pub. Date: Jul. 13, 2006

(54) Method and apparatus for inspection of high frequency and microwave hybrid circuits and printed circuit boards

(75) Inventors: Igor Shvets, Dublin (IE); Roman Kantor, Dublin (IE)

Correspondence Address: BIRCH STEWART KOLASCH & BIRCH, PO BOX 747, FALLS CHURCH, VA, 22040-0747, US

(73) Assignee: The Provost Fellows and Scholars of the College of, Dublin (IE)

(21) Appl. No.: 10/539,598

(22) PCT Filed: Feb. 14, 2003
(86) PCT No.: PCT/IE03/00022

§ 371 Date: Dec. 5, 2005

(30) Foreign Application Priority Data
Dec. 20, 2002 (IE) S020985

(51) Int. Cl. G01R 31/302

(52) U.S. Cl. 324/750

(57) ABSTRACT

The invention relates to a method and apparatus for the inspection of high frequency and microwave circuits such as printed test circuit boards. The invention uses a probe or antenna (3) which is separated from the device under test (DUT) (2). The invention provides a relatively long central protruding conductor (8) for the antenna (3) which protrudes from its shielding (7). In the method, the antenna (3) is used to acquire microwave electromagnetic field measurements in a near field region of a test pont of the DUT (2). Generally, this is done at two test positions with a difference in separation (Δl) between the apex (8) of the antenna (3) and the DUT (2). The two test results calculated and recorded and the difference of the microwave properties of the two tests is obtained to provide information about the operation of the DUT (2). The antenna (3) can be either a straight electric field antenna or loop antenna. Further, the antenna (3) can be inclined to the vertical and thus it is possible, by taking a series of measurements, to obtain both the phase and frequency of the currents being carried by the DUT (2) when it is energised.

The present invention relates to a method of assessing the operation of a Device Under Test (DUT) at high and microwave frequencies. Further, the invention provides an antenna for use in such a method and also provides a topography recording system for use in such a method.

Printed Circuit Boards (PCB), hybrid circuit assemblies and individual elements or components of these, hereinafter collectively. Devices Under Test (DUTs) need to be tested during both the development and production phases. During the development phase the tests should allow the establishment of errors in the circuit design, confirm the correctness of the choice of elements and the optimisation of the circuit layout. It is thus necessary to collect rather detailed information on currents and/or voltages in the circuit during its operation including, for example, their phase and spectral characteristics generally. During the production phase, one often needs to perform relatively simple measurements at a number of points on a circuit and compare these with readings for a correctly functioning one to enable quality control. In some cases, it allows one to perform component adjustment procedures. The requirements for testing are different during the development and the production phases. During the development phase, in-depth information is required on a relatively small number of DUTs. During the production phase one does not have to obtain in-depth information but the measurements have to be performed rapidly as a large number of DUTs have to pass through the quality control procedure.

At present, the standard method of testing employed measures the voltage signal at a number of test points by applying probes to these. There are numerous methods enabling the establishment of contacts between the DUT and the test rig through a large number of spring-loaded probes simultaneously, so-called “Bed of Nails” test technologies. Various fixtures have been developed for the Bed of Nails and related technologies. The prior art is represented for example in U.S. Pat. No. 4,017,793 (Haines); U.S. Pat. No. 4,056,733 (Sullivan); U.S. Pat. No. 4,061,969 (Dean); U.S. Pat. No. 4,115,735 (Stanford); U.S. Pat. No. 4,164,704 (Kato et al); U.S. Pat. No. 4,209,745 (Hines); U.S. Pat. No. 4,321,533 (Matrone); U.S. Pat. No. 4,322,682 (Schadwill), and U.S. Pat. No. 5,216,358 (Vaucher). Such technologies work reliably at a low frequency range, generally up to 100 MHz. For testing of unpowered PCBs, resistance is usually measured between various tracks of the board. In some cases capacitance is measured between the tracks and the ground layer (e.g. U.S. Pat. No. 4,583,042 (Reimer)). In the case of powered PCBs, voltages are usually measured at the contact probes. Generally a similar approach is taken for testing high frequency and microwave circuits. The high frequency probes are more complex and difficult to use. The high frequency contact test technologies are described in U.S. Pat. No. 4,697,143 (Lockwood et al); U.S. Pat. No. 4,593,243 (Lao et al), and U.S. Pat. No. 5,565,788 (Burr et al). In the case of high frequency and microwave DUTs such measurements are much more complex and cumbersome for a number of reasons:
1. Measurements require the setting up of special contact pads on the DUT thus imposing an additional design requirement. In the case of low frequency measurements, almost any pin of a device or printed circuit board can serve as a contact pad as it is. In the case of high frequency and microwave measurements, special contact pads with well defined properties have to be placed on the DUT just for the purpose of such testing.
2 To place a probe for high frequency and microwave testing on the DUT and to match measured signal correctly, a single probe usually has to make contact with the DUT at two or three locations or, as they are generally termed, points simultaneous and not just at one point as with a low frequency probe. Therefore surface roughness of the DUT or contamination can play a detrimental role.
3. The high frequency probes are much more complex, fragile and less durable than the low-frequency ones.
4. The impedance of the probe has to be matched at the test point so as not to affect the circuit's operation. This imposes an additional design restriction on the probe and also on the DUT: meaning that either the DUT has to be designed is such a way that all the test points have identical impedance or that several different probes have to be used to test the DUT at several points.
5. The high frequency/microwave probe is much more likely to affect the performance of the DUT than probes taking low frequency signals.

The objective of the present invention is to address these shortcomings of the test technologies at high and microwave frequencies, namely, frequencies in the range from 50 MHz to 50 GHz.

There are technologies where a PCB (generally an unpowered board) is placed in an external electromagnetic field. The board perturbs the field. The pattern of field distortion contains information about any defects in tracks of the board. This technology was developed for finding faults in unpopulated or inactive populated PCBs. The field perturbation is measured by an array of electromagnetic sensors. An example of such technology is described in U.S. Pat. No. 5,424,633 (Soiferman). A relatively similar technology is described in U.S. Pat. No. 5,006,788 (Goulette et al).

There are inventions where the sample is scanned with respect to a probe in the near-field proximity of the probe. For example, U.S. Pat. No. 5,781,018 (Davidov et a) teaches a method for characterising properties of materials such as dielectric constant or local resistivity. In this technique the microwave signal is coupled through a wave-guide probe towards the sample. The signal is reflected from the sample back into the wave-guide. Two signals at two orthogonal polarisations are compared. A similar technique is described in U.S. Pat. No. 6,100,703 (Davidov et al). Although these techniques could be beneficial for the testing of passive materials such as semiconductor wafers, they cannot be directly applied for testing active DUTs. Besides, although these techniques are capable of detecting relatively small features such as long scratches on a flat conducting surface, they cannot deliver resolution below 100 μm which is required for testing of many PCB and hybrid circuits. The specification teaches that the resolution of this technique is in the range of several millimetres as the technique utilises wave-guides that would be of a rather large size for frequencies dealt with in the present invention. Preferably, PCB test technology should not be based on a particular resonance frequency determined by the size of the probe.

There are numerous other inventions related to the same aspect of characterisation of material properties of the sample (such as local conductivity or dielectric constant) at high frequency by bringing an open ended probe in close proximity to the material. Those techniques are presented in U.S. Pat. No. 5,900,618 (S. M. Anlage et al.) and publications [C. P. Viahacos, R. C. Black, S. M. Anlage, A. Amar, F. C. Wellstood, Appl. Phys. Lett. 69 (1996), p. 3272], [D. E. Steinhauer, C. P. Viahacos, S. K Dutta, F. C. Wellstood, S. M. Anlage, Appl. Phys. Lett. 71 (1996), p. 1736] and [A Kramer, F. Keilmann, B. Knoll, R. Gickenberger, Micron, Vol 27 (1997), p. 413]. In these techniques, electromagnetic field is coupled into the sample either from the probe or from an external source. The energy, reflected back from the sample into the probe or transmitted through the sample, is measured. A similar technique is described in U.S. Pat. No. 6,173,604 (Xiang et al). The microwave energy is coupled into a probe placed in proximity to the sample. The energy reflected from the sample back into the probe contains information about the sample properties such as dielectric constant. To improve the sensitivity of the technique, the probe is placed in a quarter wavelength cavity resonator. These techniques are based on monitoring relatively strong coupling of evanescent waves between the probe and the passive sample.

Due to good sensitivity and well-defined electric properties, short cylindrical coaxial antennas are commonly used for the acquisition of microwave electric intensities in a near-field region [J. S. Dahele, A. L. Cullen, IEEE Trans. Mic. Theory Tech. 28 (7), p. 752 (1980); J. Gao, A. Lauder, Q. Ren, Wolf I., IEEE Trans. Mic. Theory Tech 46 (1998), p. 1694], and U.S. Pat. No. 5,900,618 (S. M. Anagle et al.). Also known as short monopoles, these coaxial antennas consist of a central conductor that protrudes for a defined length from a shielding. Because of the axial symmetry, such antennas are sensitive to the component of the microwave electric field parallel to that axis. The external field is commonly assumed to be homogeneous thus resulting in a single sensitivity coefficient, that is the ratio between the signal level induced in the antenna and the field intensity. The length of the protruding conductor must not exceed the desired spatial resolution. The resolution does not just depend on this length but also on the dimensions of the shielding as surface currents in the shielding induce a secondary field and change the input signal. When the field is highly localised around the apex (Up) of the protruding conductor, images with spatial resolution somewhat better than the length of the conductor and the dimensions of the shielding can be obtained. Unfortunately, those measurements lack good quantitative characterization as the antennas signal level depends on a particular distribution of the field that can no longer be considered to be homogeneous. Additionally, when the antenna length is chosen to be comparable or shorter than the shield diameter, the presence of the shielding close to the circuit may cause redistribution of the charges in the circuit and distortion of the primary induced field.

For many DUTs it is beneficial to be able to perform the measurements with a spatial resolution of 100 micrometres or better as the width of the track on a PCB is in that range. By decreasing the antenna dimensions, along with the coaxial shielding, its spatial resolution capability can be improved. Therefore, one expects that in order to make the antenna a suitable basis of the test technology, it has to be made with dimensions smaller than 50 micrometres. There are, however, numerous complications in making such an antenna. It is difficult to manufacture reproducibly the antenna alone with such small dimensions. Especially, manufacturing the coaxial probe or line with a small diameter and forming a short protruding central conductor is difficult. It is also difficult to establish a reliable and well-defined shield. Such a shield strongly influences the properties of any antenna. The second reason making it unattractive to reduce the antenna size into the micrometer range is that with decreasing the antenna size its impedance values move away from the common values of the microwave and radio frequency amplifiers. As a result, it is more difficult to couple the signal from the antenna into a preamplifier.

The objective of the present invention is to overcome the resolution limit determined by the antenna's dimensions and increase its resolution capability without the need for further miniaturization of the antenna.

The spatial resolution also depends on the gap separating the antenna and the DUT. For large separation, the resolution gets worse. Also the signal detected by the antenna depends on this separation and again the larger the separation, the smaller is the signal detected. It is, therefore, Intuitively attractive to reduce the separation to a value as small as possible. This is not, however, the best course of action for many reasons. With a small separation, the antenna starts influencing the DUT, mainly through the capacitive coupling between them. The situation with a small separation between the antenna and the surface of the DUT is effectively equivalent to a capacitor between the DUT and the antenna at the point of test. The smaller the separation, the greater the capacitor's value. This capacitance depends not only on the separation between the probe and the surface, but also on the dielectric properties of the material underneath the probe.

The optimal separation between the probe and the sample must satisfy two criteria: it has to make it possible to achieve high resolution and low coupling between the probe and the sample. As the surface of PCBs contain various features (strip edges, wire bodings, etc.) the sample profile varies and the inspection area is not flat. Accordingly, the system that controls the separation between the probe and the DUT must satisfy very demanding criteria

There are many techniques for measuring the topography of devices using scanning atomic force microscopy and scanning shear force microscopy such as described in U.S. Pat. No. 5,412,980 or publications such as [P. C. Yang, Y. Chen, M. Vanez-Iravani, J. Appl. Phys. 71 (1992), p. 2499], [R. Tolledo-Crow, P. C., Yang, Y. Chen, M. Varez-Iravani, Appl. Phys. Lett. 60 (1992), p. 2957], and [Y. Martin, C. C. Williams, H. K. Wickramasinghe, J. Appl. Phys. 62 (1997), p. 4723]. Unfortunately many of these are not suitable for use when testing DUTs with microwave probes. Most of these topography scanning techniques utilise very light topography probes, such as silicon cantilevers, usually manufactured by microfabrication processes. In some cases a combination of the topographic and field probe is employed using microfabrication technologies whereby the functional electric or magnetic field probe is fabricated as part of the Atomic Force Microscope (AFM). The topography probes are mostly based on mechanical resonance of the probe and changes in resonance conditions caused by the proximity of the device surface. These probes operate very close to the device, normally with a separation in the range of 1-50 nm at which a large capacitive coupling between the probe and DUT is virtually unavoidable. The probes can be withdrawn out of the sample for measurements of various probe-sample interactions at higher distances, as described in the U.S. Pat. No. 5,418,363 (Ellngs et al.) and various publications referred therein. A probe of small mass is crucial to assure good sensitivity in scanning atomic force microscopy and shear force microscopy. Some of the probes combine the tip probe with integral small electric or magnetic field antenna U.S. Pat. No. 5,936,237 (Van der Welde, D. Warren) teaches the combination of the electromagnetic probe with the probe of an Atomic Force Microscope (AFM) in a single multipurpose probe. The measurement of the electromagnetic coupling between the probe and the device can be theoretically suitable for testing materials at frequencies up to above 1 THz. Although it may be possible to fabricate micrometer size probes capable of providing high resolution at THz frequencies, it is suggested that the use of such miniature probes for PCB testing in the microwave frequency range (50 MHz to 50 GHz) with any kind of satisfactory performance is very difficult, if not virtually impossible. This is due to the fundamental relation between the probe size and the sensitivity of the probe for the frequencies of interest and also the practical requirements due to the DUT's size and shape. These reasons limit the possible use of such existing technologies to the inspection of semiconductor wafers and the study of materials properties of relatively flat samples.

A quartz tuning fork is commonly used in Atomic Force Microscopy (AFI) and Scanning Near-Field Optical Microscopy (SNOM), for control of the distance between the probe and the sample. The technique incorporated a dithored probe interacting with a surface in its proximity. The dependency of the amplitude and the phase of the probe's mechanical oscillation on the probe/sample separation is used in a feedback to keep the separation constant. The tuning fork is utilized for the stabilization of the mechanical oscillations of the probe and the detection of the amplitude of the mechanical resonance. The method was originally introduced by Karrai and Grober [Karrai K., Grober R. D., Appl. Phys. Lett 66, p. 1842 (1995)]; and U.S. Pat. No. 5,641,896 (Karrai). Various modifications of the system were proposed: with the probe oscillating either parallel or perpendicular to the surface (publication [Tsai D. P., Yuan Y. L., Appl. Phys. Lett. 73, p, 2724 (1998)] and U.S. Pat. No. 6,373,049 (Isal)), with both or only a single arm of the tuning fork [Kantor R., Lesnak M., Berdunov N., Shvets I. V., Appl. Surf. Sci 144-146 (1999), p. 510] with additional balancing weight on the second arm of the tuning fork as presented in U.S. Pat. No. 5,939,623 (Muramatsu) or with a biasing member pushing the probe into pressure contact with the quartz oscillator (Yomita, U.S. Pat. No. 6,201,227.

The oscillations in the tuning fork systems are usually excited by an external piezo tube, bi-morph, thickness or shearing mode piezo plate, and not by the application of the signal directly on the fork electrodes. Thus the piezo-electric properties of the quartz tuning fork as a self-oscillating resonator are disregarded. The reason advanced for the use of an external dithering piezo is that the quartz tuning fork resonator operates with a much lower quality factor (which drops by more than 2 orders of magnitude from their original value), caused by additional damping forces: air damping, non-elastic deformation within the system with the tip attached and drag forces of the tip/sample interaction. The ratio between the piezoelectric response signal and the amplitude of the excitation is directly proportional to the quality factor. Therefore, the level of the piezoelectric response with external excitation is also 2 orders of magnitude lower than that of standard quartz crystal applications and tend to be 10-100 times below the level of the amplitude of the excitation signal. Such low response is difficult to isolate from the original excitation signal, thus separate systems for mechanical dithering are usually used to electrically isolate both signals. A typical configuration has a dithering piezo such as a thickness mode piezo and a probe connected to one of the two arms of a fork and oscillating parallel to the surface. A generator supplies an excitation signal to the thickness mode piezo. The generator also supplies a signal to the reference input of a lock-in amplifier (LIA) through a phase shifter. The detection signal is collected from the electrodes of the tuning fork crystal and supplied to the input of the LiA.

A self-excitation regime of the fork has been described by Chuang et al., [Chuang Y. H., Wang C. J., Huang J. Y., Pan C. L, Appl. Phys. Lett. 69 (1996), p. 3312] where a time-gating method was incorporated, In that method the excitation signal is multiplexed with an oscillation-sensing response by an electronic switch. This switch is triggered in sub-millisecond intervals, allowing separation of both signals. The disadvantage of this method, apart from the additional electronic instrumentation, is in the aliasing between the frequency of the oscillator and the frequency of the electronic switch gate. Conditions for the measurements have to be carefully chosen to avoid such aliasing, usually the frequency of the trigger signal has to be an order lower than mechanical resonance frequency. This results in a slower response and a longer time constant of the feedback system.

### STATEMENT OF INVENTION

According to the invention, there is provided a method of assessing the operation of a device under test (DUT) at high and microwave frequencies comprising using an antenna terminating in a, tip or apex to acquire microwave electromagnetic field measurements in a near field region of a test point of the DUT comprising the steps of:—
siting the antenna in a test position with its tip at a predetermined distance and at a predetermined inclination to the test point;
energising the DUT; and
measuring and recording a microwave property of the DUT.

This provides a solution to the major problem with the prior art, namely, the need to establish a low resistance contact between a high frequency or microwave probe and the DUT. The invention overcomes the problem that the resistance influences the working regime of the DUT and the hitherto experienced increase of the mutual coupling between the probe and the DUT. The results heretofore of the measurements have been relatively meaningless. By this separation of the probe from the DUT by a relatively large gap, there is very weak coupling between them.

Further, the invention provides the additional steps of:—
displacing the antenna along its axis to site the antenna at another test position a predetermined distance and at substantially the same inclination to the test point;
measuring and recording the microwave property; and
calculating and recording the difference in the microwave properties to provide information about the operation of the DUT.

This gets over all the problems of interference and the field surrounding the conductor apex can be isolated and measured which greatly improves the spatial resolution of the microwave field mapping.

The antenna is displaced a distance between 1 μm and 50 μm.

In one embodiment of the invention, the inclination of the antenna is substantially orthogonal to the DUT.

In another method according to the invention, the antenna is sited at an inclination to the vertical and the method comprises the additional steps of:—
rotating the antenna about its apex by a predetermined rotation angle, while maintaining its inclination to the vertical;
measuring and recording the microwave property;
calculating and recording the difference in the microwave properties to provide information about the operation of the DUT.

The predetermined rotation angle may be substantially 180° or may be rotated at rotation angles of substantially 120° and 240° to obtain three sets of measurements. In this way, different spatial components can be measured and, for example, with two measurements with the antenna rotated by 180° around the normal axis, a vertical and one tangential field density can be obtained, while with the three measurements, three components of the signal can be obtained. Both the amplitude and the phase of signal can be acquired by a phase sensitive VNA.

Ideally, the inclination ir of the order of 45°. Further, with the present invention, the sensitivity of measurement of the electrical field intensity at a particular frequency is defined by

$$S = \frac{Δ U}{{E}_{l} Δ l}$$

where:
   ΔU Is the voltage difference of antenna signal measured for two positions of the antenna displaced along antenna axis;
   Δl is the displacement of the test positions;
   E₁ is the component of the electrical field intensity of the microwave field parallel to the antenna axis; and
   S Is a sensitivity constant
and in which
the sensitivity constant (S) is determined by a calibration measurement in a well defined field standard and is subsequently used to determine the real value of the electrical field intensity of a DUT during a test.

It will be appreciated that microwave property of the DUT can be one of the amplitude, phase or frequency of the voltage detected by the antenna.

Preferably, the test position is chosen to minimise the capacitive and inductive couplings between the antenna and the DUT while providing a sufficiently strong signal.

Ideally, the test position is at least spaced-apart from the DUT by a distance greater than the widest lineal dimension of the lip of the antenna facing the DUT.

Practically, the separation between the tip of the antenna and the test point of the DUT is between 1 μm and 100 μm.

The present invention operates within the frequency range of operation is between 50 MHz and 50 GHz, and ideally operates within the range 300 MHz and 30 GHz.

Further, in accordance with the invention, the siting of the antenna comprises:—
moving a topography probe, attached to a quartz crystal oscillator to a probe position adjacent the DUT;
fixing and recording the probe position;
measuring the offset distance between the probe and the antenna apex using a separate offset distance measuring device; and
positioning the antenna apex above the same point of the DUT by taking into account the offset distance and displacing the antenna by an additional distance along the antenna axis.

This is a much simpler construction than conventional ones. By using this construction, there is no need for an external piezo element and therefore a much simpler and less expensive apparatus is provided.

In one embodiment of the invention, the topography sensing system comprises an excitation generator to operate at the resonance frequency of the probe and means to extract the oscillation response signal of the probe from that of the excitation signal based on the orthogonality of the phases of those signals and hence a measure of the distance of the probe from the DUT.

In order to measure the offset distance the topography probe is brought into a focus point of a long focal length microscope and the antenna are brought to the same focus point to measure the offset between the positions of the probes.

In one method according to the invention, the test position is recorded relative to a datum point of a fixture for reception of the DUT and this test position is used for subsequent similar DUTs placed on the fixture.

In this latter way of carrying out the invention, the test position for a number of similar DUTs is recorded, averaged and used to provide the test position for subsequent similar DUTs.

In one method according to the invention, a plurality of DUTs which have been determined to function correctly in practice are measured at one or more test points and the resultant measurements recorded as acceptable measurements for subsequent DUTs measured at these test points.

Further, the invention provides an antenna for use in the method defined above, comprising a coaxial shielding and a protruding conductor therefrom in which the length by which the conductor protrudes from is shielding substantially exceeds the greatest lineal dimension of the shielding adjacent the conductor to isolate the effects of the shielding from the DUT. This has been found to be an efficient configuration with low perturbation of the signals in the DUT as the shielding body is relatively distant from the measured sample and thus the problems of the bulky part of the antenna inducing perturbation is reduced.

In one embodiment of the invention, the antenna is a coaxial antenna and in which the length by which the conductor protrudes exceeds, by at least a factor of two, the external diameter of its coaxial shielding and by at least the same factor, the smallest dimension of the feature at the DUT that needs to be resolved. Preferably, this factor is at least three.

Further, the invention provides a topography sensing system for use in the method defined above comprising:—
a quartz crystal oscillator;
a topography probe connected to the oscillator;
an excitation generator having means to operate at the resonance frequency of the oscillator with the probe; and
means to shift the phase of the oscillation frequency of the probe from that of the oscillation signal and to extract the oscillation signal as a measure of the distance between the probe and the topography.

Further, the invention provides a topography sensing system for determining the vertical height above a DUT in the method described above, comprising:—
a holder;
control means for moving the holder vertically with respect to the topography;
a probe being supported in the holder in a rest position and freely movable upwards within the holder on the tip contacting portion of the topography;
means to record displacement of the probe on contact being made to measure the distance of the holder from the portion of the topography with which contact was made.

This has the great advantage of giving additional speed and accuracy. It allows the testing of a greater number of DUTs to be performed.

In this latter embodiment, the holder comprises a bored tube and the probe is a stiff rod mounted within the tube.

It will be appreciated that what the present invention does is to separate the probe and the DUT by a distant gap leading to weak coupling between them. The measurements are based on an antenna that detects the non-radiative electric and magnetic fields emitted by the DUT in the near field region for such circuits, which heretofore was not possible.

The invention will be more clearly understood from the description of some embodiments thereof, given by way of example only, with reference to the accompanying drawings, in which:—

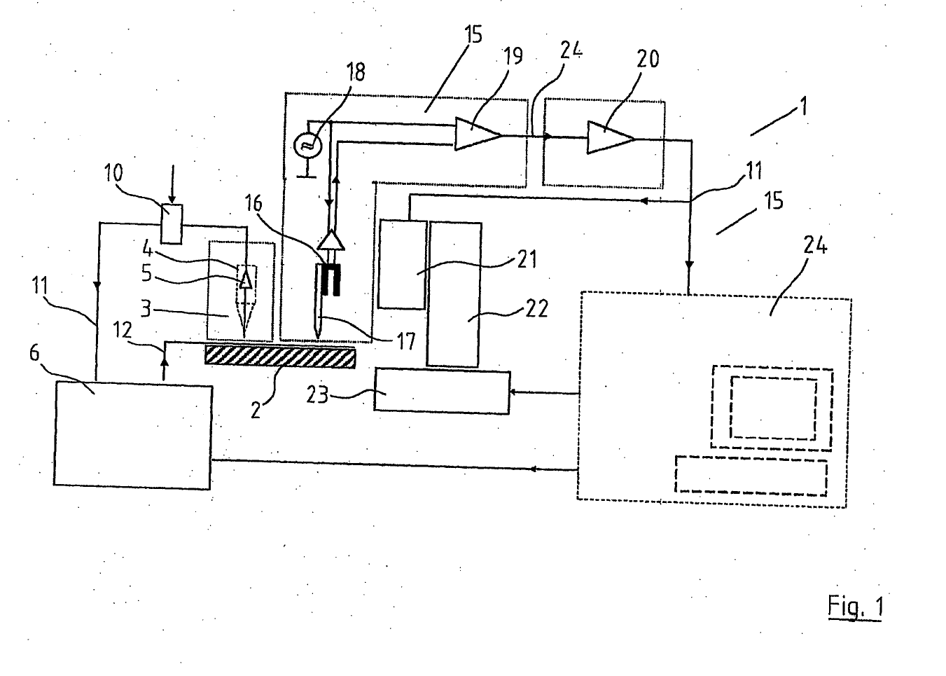

FIG. 1 is a general schematics of the apparatus according to the invontion,

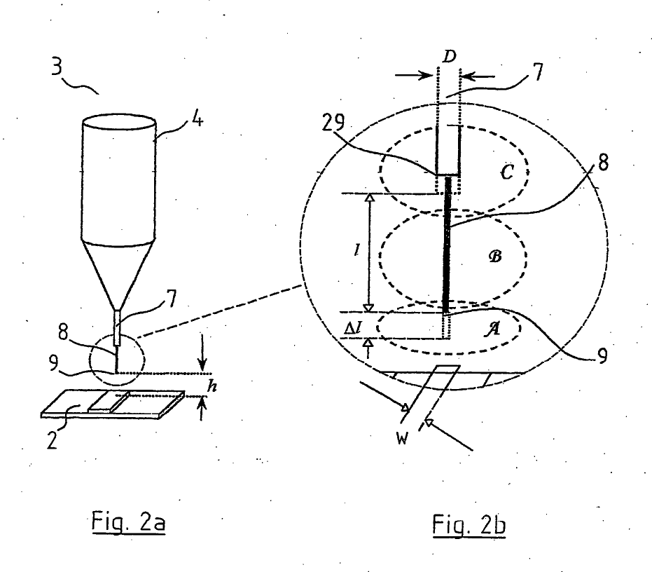

FIG. 2(a) is a diagrammatic view of an electric field antenna used in the invention,

FIG. 2(b) is an enlarged view of portion of the antenna encircled in FIG. 2(a),

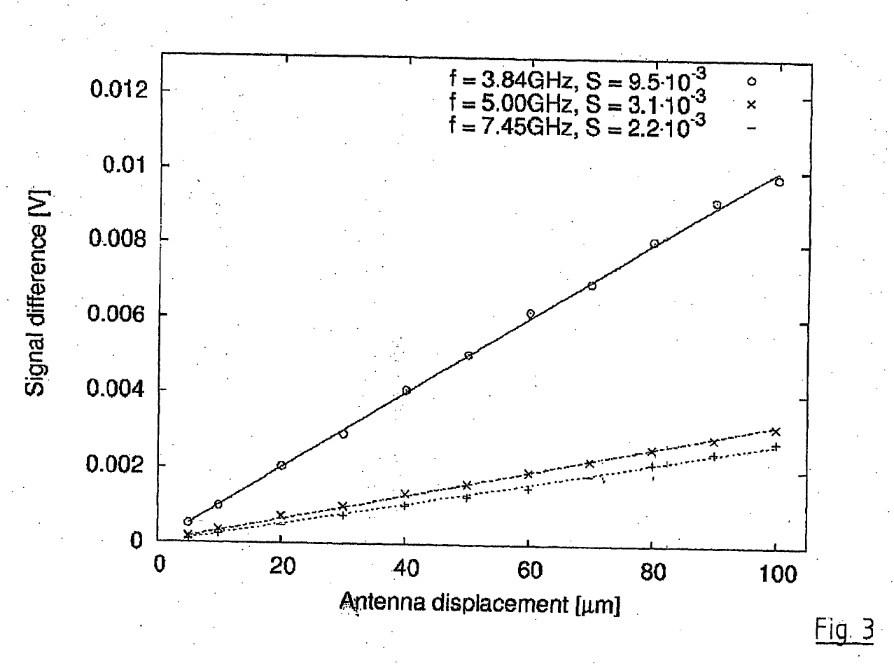

FIG. 3 is a graph illustrating the effect of antenna displacement,

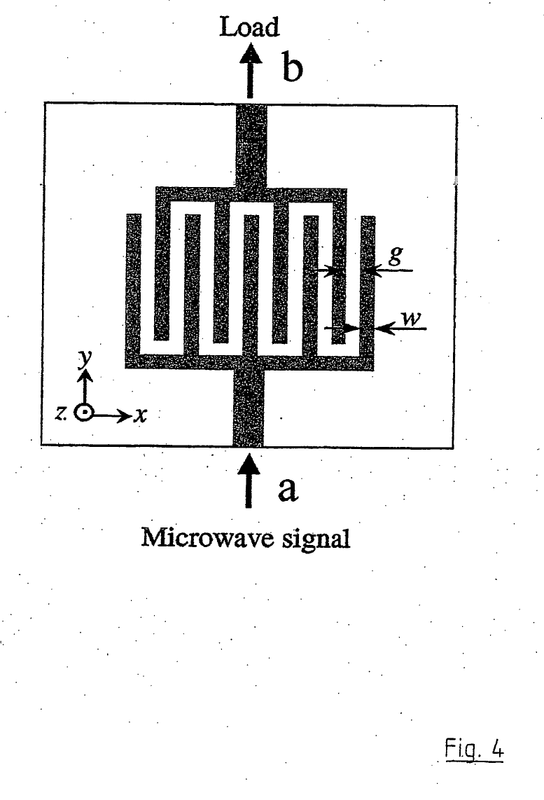

FIG. 4 is a plan view of a DUT used to test the invention,

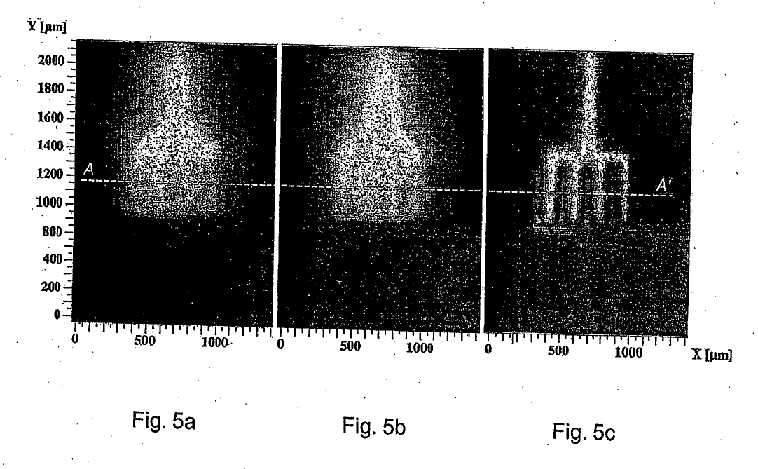

FIGS. 5(a) to 5(c) illustrate results obtained in accordance with the invention,

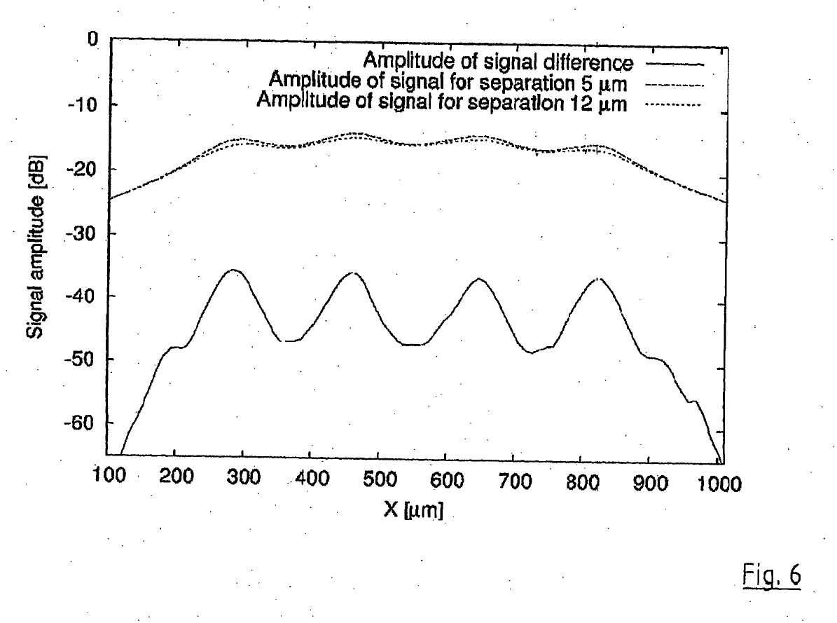

FIG. 6 shows results obtained in accordance with the invention, as one example of the results illustrated in FIG. 5 for magnitude of the microwave electric field,

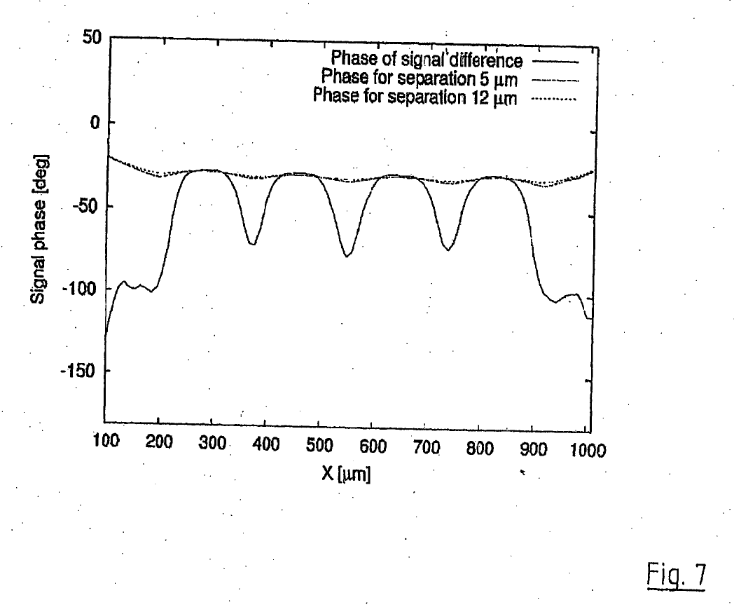

FIG. 7 is a view similar to FIG. 6 of another result of an experiment carried out representing phase of the measured microwave field,

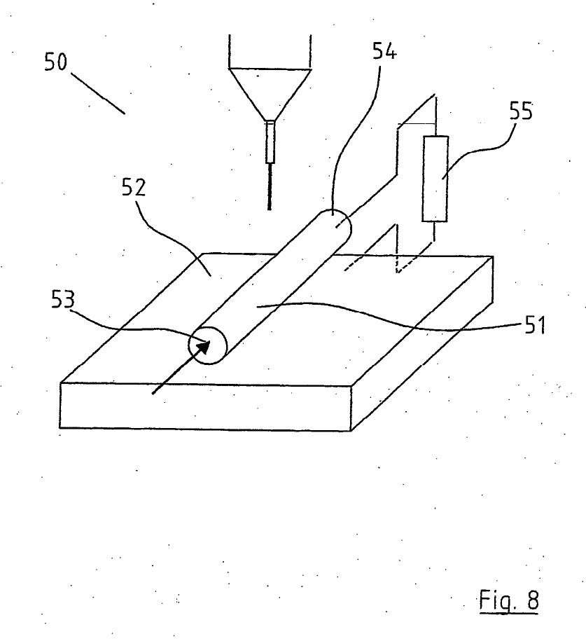

FIG. 8 is a schematic view of an antenna calibration unit,

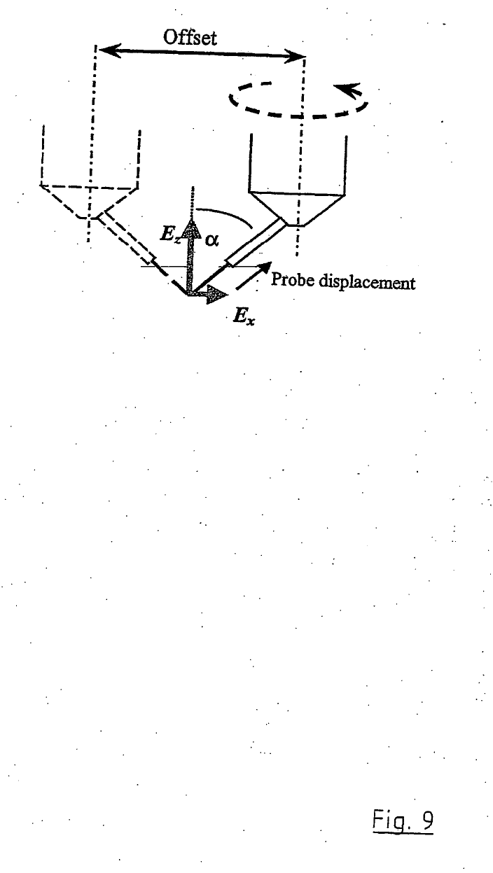

FIG. 9 illustrates operation as required to measure horizontal components of the field according to the invention,

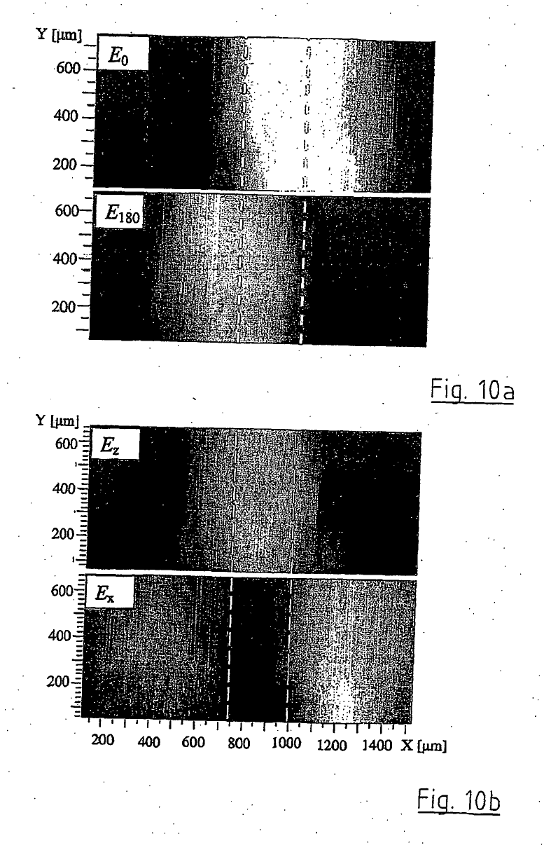

FIG. 10(a) and FIG. 10(b) show results obtained by using inclined coaxial antenna as illustrated in FIG. 9,

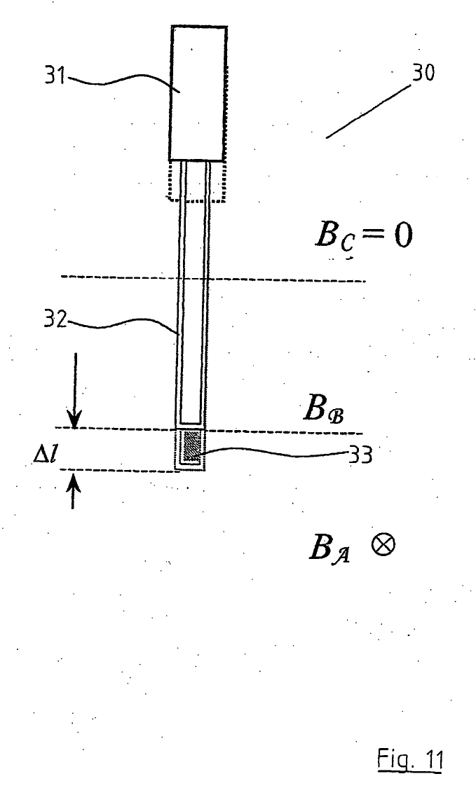

FIG. 11 is a view similar to FIG. 2 of a loop antenna according to the invention,

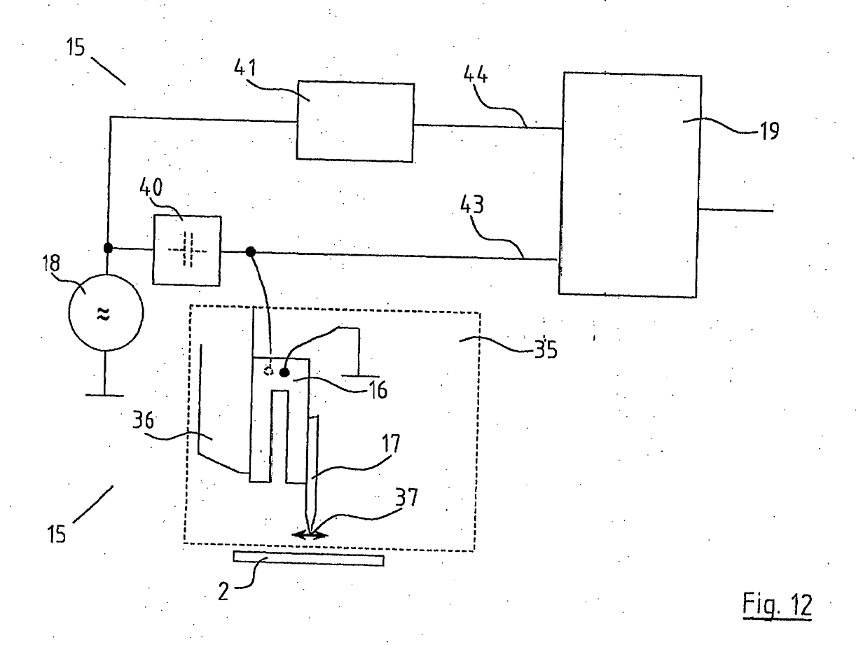

FIG. 12 is a diagrammatic view of one distance control system according to the invention,

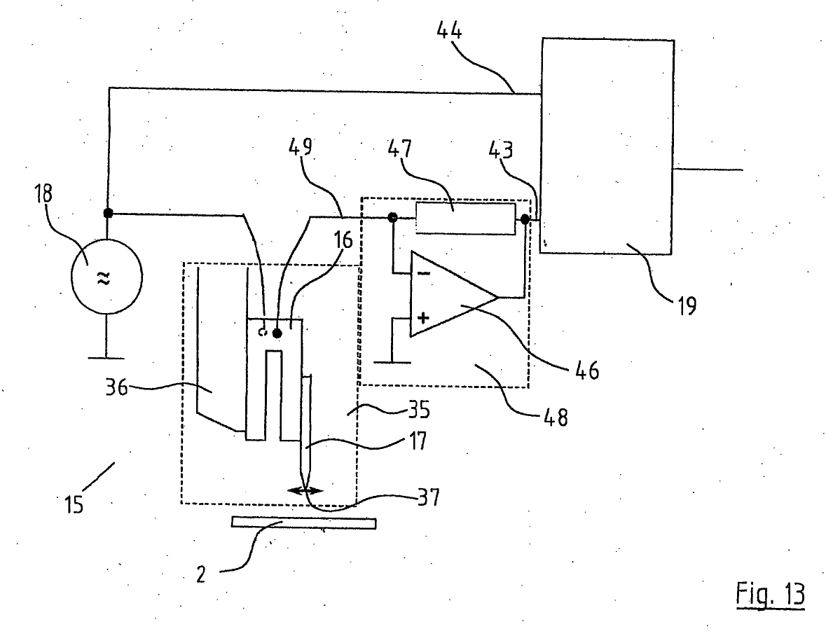

FIG. 13 is a view similar to FIG. 12 of a further distance control system according to the invention,

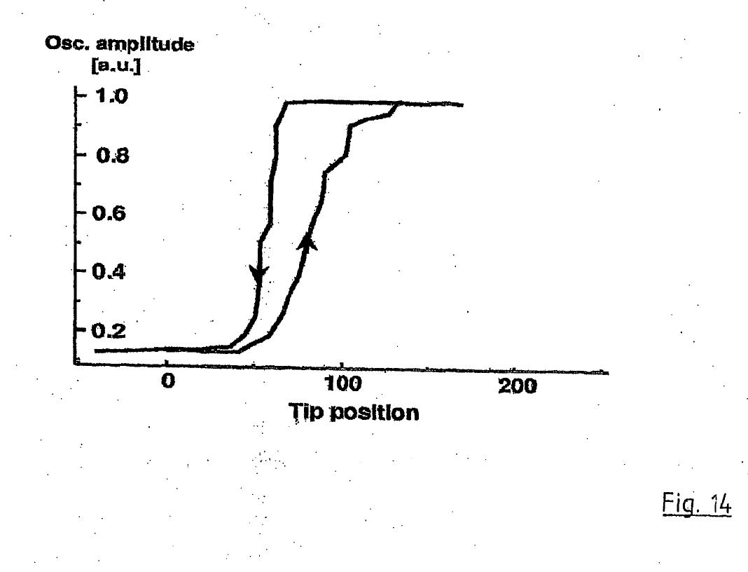

FIG. 14 shows the response of a topography probe according to the invention, and

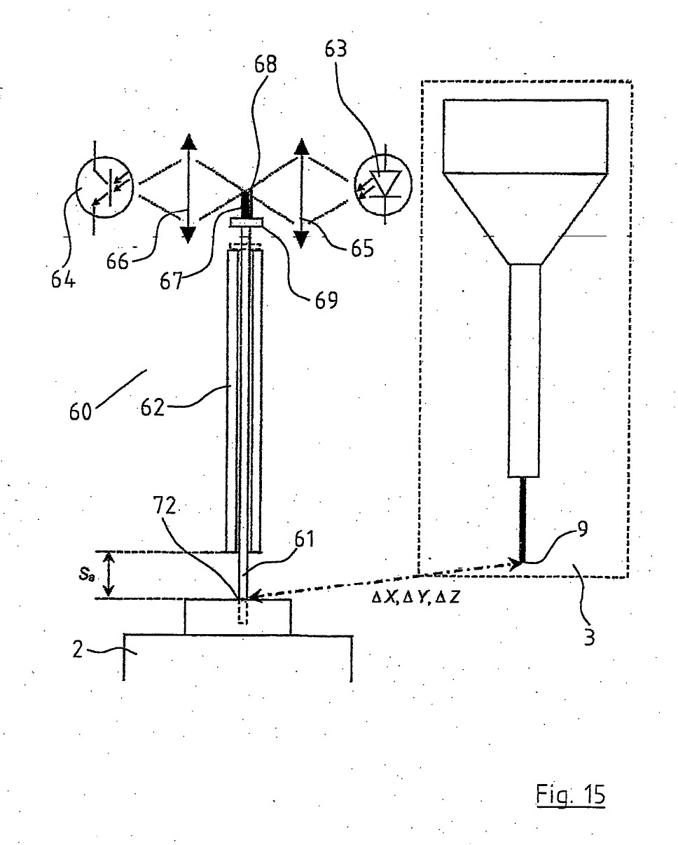

FIG. 15 is a view of a topography sensing system for fast measurement of the elevation of the DUT surface.

Referring to the drawings and initially to FIGS. 1 and 2 thereof, there is illustrated apparatus, indicated generally by the reference numeral 1, for the inspection of high frequency properties of a DUT 2, above which is mounted a field antenna, indicated generally by the reference numeral 3. The field antenna 3 which is illustrated partly by interrupted lines is illustrated in more detail in FIGS. 2(a) and (b) and comprises an antenna case 4, shown by interrupted lines in FIG. 1, mounting within it a conditioning RF preamplifier 5, only illustrated in FIG. 1. There are also mounted within the antenna case 4 various signal conditioning devices for transmission to the input of an acquisition instrument, in FIG. 1, a vector network analyser 6. The field antenna 3 further comprises antenna coaxial shielding 7 mounting a central protruding conductor 8 having an apex or tip 9. The output signal from the antenna 3 is connected by a transmission line 11 to the vector network analyser 6. The DC bias for the preamplifier 5 is coupled from an external source by a bias coupler 10. The high frequency signal which energizes the DUT 2 is provided by an RF output of the VNA and coupled by a signal line 12. The apparatus 1 further comprises a topography sensing system, indicated generally by the reference numeral 15. The topography sensing system 15 is one based on measuring shear forces when a tip is dithered parallel to a surface such as a DUT surface. The topography sensing system 15 comprises a tuning fork or quartz crystal oscillator 16 connected directly to a probo 17. The topography sensing system 15 further comprises a circuit, including a generator 18, a lock-in amplifier 19 and a conditioning feedback amplifier 20. There is also provided a pier actuator 21 for fine adjustment of the probe's 17 position relative to the DUT 2 and further motorised positioning stages 22 and 23 for the probe 17. The motorised positioning stage 22 is a vertical Z axis positioner and the motorised positioning stage is a two stage horizontal X and Y axis positioner. The apparatus 1 further includes a control computer 24.

Before describing in more detail the critical operation of the apparatus and the construction of the antenna 3, it is advantageous to give a brief overview of the operation. The first thing that is required is to achieve precision of antenna positioning. Thus, the topography of the DUT surface is measured by the topography sensing system 15. In operation, to obtain the topography, the vertical position of the probe 17 is adjusted by the piezo-actuator 21 to keep the separation between the apex or tip of the probe 17 and the DUT 2 in the range of shear force interaction. The motorised positioning stage 22 and the piezo-actuator 21 are used for vertical displacement of the probe with the latter being used for fine operation. The motorised stage 23 operates in two horizontal directions. The position of the probe 17, defined by the displacement of the motorised stages 22 and 23, and the value of the driving signal for the piezo-actuator 21 that are stored in the computer 24.

For the field measurement, the topography probe 17 is removed and the antenna 3 placed in position and driven in accordance with the topographic data, by the piezo-actuator 21 and the motorised stages 22 and 23 so that the tip 9 is correctly positioned at required distance from the DUT 2.

Further, while in the embodiment described above, a vector network analyser was used for the acquisition of the signals, it will be appreciated that any other suitable acquisition system could be used.

Further, in operation, as will be described in more detail, the antenna 3 is positioned above and in the near field region of a test point of the DUT 2 and, as illustrated in FIG. 2 orthogonal thereto, the DUT 2 is energised and then the microwave signal induced by the OUT 2 is measured and recorded. In the particular embodiment, the signal corresponds to the electrical component of the microwave field. Then, the antenna 3, as described below, is moved relative to this position in a vertical or an inclined orientation. As described below, in a first method, it is moved orthogonal to the DUT 2.

Referring again to FIG. 2(a) and FIG. 2(b), the coaxial shielding 7 has a diameter D and the central protruding conductor 8 has a length l. In practice, the antenna case 4 is a hollow cylinder 15 mm long, with an outside diameter of 6 mm and an inside diameter of 4.5 mm holding various circuitry. This is terminated by an SMA connector for signal output and DC bias for the preamplifier.

The protruding conductor 8 is relatively long. It is crucially important that unlike in many state of the art devices, this protruding conductor 8 substantially exceeds both the diameter D (typically D=0.1−0.5 mm) of the coaxial shield 7 and the size w of the measured signal line, normally the track width of the DUT where typically the signal would be transmitted.
l>3D,3w (1)
whichever (D or w) is greater. Such a configuration allows low perturbation of the signals in the DUT 2 as the shielding body is relatively distant from the measured sample, otherwise that bulky part of the antenna 3 is bound to induce perturbation if brought into proximity of the DUT. If the length l of the protruding conductor 8 is too short and thus the distance between the antenna coaxial shielding 7 and the signal line, i.e. the width of the strip conductor of the DUT 2, the shielding 7 start affecting the signals within DUT 2 and changes its performance. Usual lengths l and the diameters d of the central protruding conductor are l=0.2−3 mm and d=5−50 μm respectively, for the transmission lines with width within the range of 30 μm-0.5 mm, but may be bigger for larger structures. On the other hand, as described above, one would expect that the resolution should be comparable to the length of the central protruding conductor and, with the present invention, normally stay within the range of about 0.2-3.0 mm.

Referring again to FIGS. 2(a) and 2(b), the effect of moving the antenna 3 a small distance Δl towards the DUT 2 needs to be considered. For planar microwave circuits the strength of the field is greatest close to the circuit surface and decays with increasing distance from the surface. For thin, short antenna (d<<l, k<<λ), placed in such a non-homogeneous field, the signal level can be approximated as a sum of the field contributions acting along the protruding conductor 8. If we split the antenna interaction areas along the protruding conductor into three regions—the region A of the antenna apex 9, middle region B of the antenna protruding conductor 8 and the region C surrounding the input to the coaxial shield 7 the resulting signals I₁, I₂ before and after antenna displacement, can be formally written as
I₂=I₁^{A}+I₁^{B}+I₁^{C}
I₂=I₂^{A}+I₂^{B}+I₂^{C} (2)

The signal levels are described as the induced currents I₁, I₂ at the input to the coaxial shielding as the impedance of such short antennas are high in comparison with the input impedance of the subsequent network and therefore the antenna functions as a current source. Geometry and the position of the protruding conductor 8 in the middle region B does not change with the antenna displacement and therefore the contribution from the same external field remains substantially unchanged, I₁^{B=I}₂^{B} For high-density planar structures, when the condition of equation (1) is fulfilled, the field intensities rapidly decay with the increase of the distance above the DUT 2, the field strength in the region C, and its contribution to the overall signal can be supposed to be negligible, I₁^{C}=I₂^{C}=0. The measured signal difference can be calculated as follows.
ΔI=I₂=−I₁−I₂^{A}−I₁^{A} (3)

Thus, the signal level depends only on the field solution and changes in the boundary conditions at the apex 9 of the protruding conductor 8. As these changes are limited to the region Δl of the displaced antenna apex, the measured signal and the resolution of the measurement method are determined by the displacement Δl. In this way the field surrounding the conductor apex can be isolated and measured which improves the spatial resolution of the microwave field mapping.

The above analysis shows that one can improve the resolution by reducing the displacement Δl. Unfortunately, reducing Δl leads to a reduction in the signal level. Both mathematical simulations and the experimental results, presented in FIG. 3, give a highly linear character of this dependency. Needless to say, that instead of withdrawing the antenna away from the DUT 2 by a small distance Δl one could equally well move it towards the DUT 2 for as long as the value Δl is small by comparison with the separation h between the apex 9 and DUT 2.

Referring to FIGS. 4 and 5, the scanning measurement of a DUT 2 demonstrates the benefit of the invention. For these measurements, the protruding conductor 8 of the antenna 3 had a length of 1 mm and a diameter of 8 μm. The DUT 2 was in the form of a PCB surface capacitor with a small separation gap between its fingers is illustrated in FIG. 4. The capacitor was fabricated on a substrate with a dielectric constant ε=10.2 and a thickness t=127 μm. The width of the fingers was w=40 μm, they are separated by a gap g=60 μm. Terminal a of the capacitor forms the input terminal connected to a microwave generator, in this example, the source of a HP 8720 vector network analyser and terminal b is the output terminal, connected to a quarter-wave resonator for excitation to higher potentials.

The antenna 3 in the test was driven using M-405 and M-415 (Physik Instrumente) precision motorized stages close to the sample surface of the DUT with a specified separation h above the circuit (see FIG. 2(a)). This separation must be sufficient to avoid both capacitive and inductive coupling between the tip 9 of the antenna 3 and the DUT 2. 5 μm was deemed sufficient. The DUT 2, that is to say, the PCB surface-capacitor, was then scanned for two different separations and then the signals subtracted.

Two scans were performed, FIGS. 5(a) and 5(b) represent scanned field images of the normal electric field acquired for two different antenna with DUT separations of 5 μm and 12 μm respectively. FIG. 5(c) is the difference of these signals. It can be dearly observed that there is a significant resolution enhancement for the signal difference. As the antenna is sensitive to the field acting along the entire length of the protruding conductor, the scattered field intensities at higher distances above the sample represent the main contribution to the level of the acquired signal. The signal difference corresponds to the local electric field intensities surrounding the antenna apex only. The signal difference also reveals weak local field intensities close to the signal lines of the bottom port of the capacitor, otherwise masked by strong background signals. These signals are induced by background fields acting along the whole length of the protruding conductor above the displaced apex of the antenna.

Referring to FIG. 6, there is illustrated a line scan A-A′ across the middle of the capacitor as indicated in the FIG. 5. Considerable enhancement in amplitude spatial contrast, is achieved when the amplitudes of the signals at 5 μm and 12 μm separation are subtracted from each other, this difference is represented by a solid line. It should be noted that the vertical axis presenting the signal level is logarithmic (in dB) the signal difference is naturally significantly smaller than each of the two signals.

According to the invention, one can also measure the phase of the electric or agnetic field. Indeed, the signals presented in FIGS. 5(a) and 5(b) are vectors represented by complex amplitudes of electric field intensities E and measured voltages U) and they are characterised not only by the magnitude but also by phase. Therefore, their difference is also a vector that is in turn characterised by phase. This is demonstrated in FIG. 7 which corresponds to the same cross-section as presented in FIG. 6. The increase in the phase contrast is caused by the fact that phase of the localised microwave field close to the DUT, represented by the signal difference, varies significantly as opposed to the phase of the average field at greater distances, as acquired by the entire antenna length and presented by the individual measurements.

Referring again to FIG. 1, the antenna is connected to the preamplifier 5 and in a typical embodiment the antenna and the preamplifier form mechanically a single component. As a typical preamplifier is also highly linear, the measured voltage difference ΔU corresponding to the two antenna positions after its conditioning and transmission to the input of the acquisition instrument (VNA) is proportional to the antenna displacement Δl. We can therefore define the sensitivity of the system for a particular frequency by a single unit-less constant

$$S = \frac{Δ U}{{E}_{l} Δ l} \qquad ( 4 )$$

Here E₁ is the amplitude of the component of the electric field intensity of the microwave field parallel to the antenna axis. The sensitivity constant S can be determined from the calibration measurement in a well-defined field standard and can be used during the scanning process for the calculation of real values of the electric field intensity. The design of this specific antenna, employed to obtain results shown in FIGS. 3, 5, 6, 7 was optimised for higher sensitivity S at frequencies close to 4 GHz.

Referring to FIG. 8, the measurement of sensitivity constant S was performed using an antenna calibration unit, indicated generally by the reference numeral 50, using a well-defined field standard as presented in FIG. 8. The term “field standard” as used in this specification is substantially a circuit with well-defined geometry so that the surrounding field generated by the field standard, can be calculated (without measurement). When used for probe calibration, such a device can be called a calibration unit as the detected signal can be compared with the calculated theoretical field intensity. The field standard represents a 50Ω transmission line consisting of a cylindrical conductor 51 placed above ground plane 52. A microwave signal of known amplitude is coupled to one port 53 of the line and the other port 54 is terminated by a 50Ω load 55 to avoid reflection of the signal. Such a configuration allows calculating the electric field E at any point above the field standard. Therefore, by placing the antenna at a given point and measuring the signal detected by it the sensitivity S of the antenna can be obtained using equation (4). The results of calibration measurements were already presented in FIG. 3 for various probe displacements Δl.

The level of the acquired signal depends not only on the signal induced in the apex of the conductor but also on the efficiency of its matching to the input of the coaxial line, the properties of the preamplifier and the transmission of the signal to the acquisition system (usually a VNA). As the signal level must exceed the noise level, the sensitivity of the antenna may effectively limit its resolution and make it dependent on minimal detectable field intensities. For small displacements Δl the apex of the protruding conductor functions as a near ideal current source and one of the main factors influencing the sensitivity is the matching of such a high-impedance source to the input of the coaxial fine and subsequently to a preamplifier. In one practical embodiment of the invention, the signal was conditioned by an MGA-86576 MMIC preamplifier. Unfortunately its standard input impedance of 50Ω represents a great mismatch to the high impedance of the antenna. To improve the matching efficiency, the input impedance of the protruding conductor has to be adjusted by an impedance matching circuit. A relatively simple matching scheme was chosen which uses the antenna coaxial input line as a quarter-wavelength transformer. Thanks to its relatively high characteristic impedance of 120Ω and by setting its length to equal to λ/4 (8 mm) for the frequency of interest (4 GHz), the level of the signal and the antenna sensitivity was increased by 15 dB to about 10 V/m for displacement Δl=30 μm. As explained above, the separation of the tip of the antenna from the DUT should not exceed the desired resolution but it should the greater than the diameter of the protruding end of the antenna to avoid direct capacitive coupling between the antenna apex and the DUT. The range of some 10-100 μm is practical for protruding wire conductors with diameters of 5-30 μm. The measurement process is further complicated by the fact that most DUTs are not flat and contain complex topographical features such as electronic elements, wires, air bridges etc. Therefore, it is vital to control the separation between the end of the antenna and the DUT while maintaining this distance in that range with small-error.

FIG. 9 demonstrates how the in-plane (tangential component of the electric and magnetic field can be measured. For these measurements the antenna is placed with an inclination of 45 degrees (for example) relative to the vertical axis. By rotating the antenna about the vertical (normal) axis, different spatial components can be measured. Standard Cartesian intensities, perpendicular and parallel to the surface of the DUT can be then calculated. In the case of two measurements with the antenna rotated by 180 degrees around the normal axis, a vertical E_{z} and one tangential Eₓ field intensity can be obtained.

$${E}_{z} = \frac{1}{2 cos α} ( {E}_{0 °} + {E}_{180 °} ) \\ {E}_{x} = \frac{1}{2 sin α} ( {E}_{0 °} - {E}_{180 °} ) \qquad ( 5 )$$

Here Eₙ°,E₁₈₀° are the electric field Intensities before and after the probe rotation. FIG. 9 shows the position of the coaxial antenna before and after rotation by 180 degrees. After the rotation the antenna must be displaced along the horizontal direction so that the antenna's end is located above the same point of the DUT. Effectively, this is a rotation about the apex of the antenna. For three measurements with the antenna rotated by 0, 120, 240 degrees all three components can be calculated.

$${E}_{x} = \frac{1}{sin α} ( 2 {E}_{0 °} - {E}_{120 °} - {E}_{240 °} ) \\ {E}_{y} = \frac{1}{\sqrt{3} sin α} ( {E}_{120 °} - {E}_{240 °} ) \\ {E}_{x} = \frac{1}{3 cos α} ( {E}_{0 °} + {E}_{120 °} + {E}_{240 °} ) \qquad ( 6 )$$

In general the field can be elliptically polarised and the phase of the field intensifies may vary for different spatial directions. Therefore, both the amplitude and the phase of the signal should be acquired by a phase-sensitive VNA and the intensities of the electric fields in equations (5) and (6) represent complex amplitudes of the signal. FIG. 9 shows a configuration with electric field coaxial antenna, however, loop antenna can be used for the measurements of all spatial components of the magnetic field in the same manner.

Referring now to FIG. 10, there is illustrated tangential components acquired using a 45° inclined antenna. The measurements were performed above a mlcrostrip line, the position of the strip edges are highlighted by dashed lines. The antenna was rotated in two opposite directions perpendicular to the strip, effectively aligning the antenna at angles of +45° and −45° relative to the normal of the DUT plane. In this experiment the distance from the circuit surface was chosen to be relatively large (600 μm) as the tangential components are negligible close to the circuit surface and vanish at the conductive boundaries of the strip or ground plane. As the rotation about the vertical axis changes the probe's position above the DUT 2, the probe was offset between the measurements so that the apex of the central protruding conductor is located at the same point for both measurements. For each direction two scans were performed with antenna displaced by 50 μm along the protruding conductor, their difference represent the field intensities at the antenna apex 9 (FIG. 10a). Normal E_{z} and transverse Eₓ electric field components, as presented in FIG. 10b were obtained using equations (5). As expected the transverse component Eₓ vanishes at the strip center where the vector of electric intensity is perpendicular to the surface of the DUT 2. This component has its maxima close to the strip edges with opposite directions of the field vector.

In the same way one can achieve enhancement of the resolution when measuring the amplified and phase of the magnetic field. In this case one needs to use a loop antenna instead of the coaxial probe. This is schematically shown in FIG. 11 for two positions of a loop antenna, indicated generally by the reference numeral 30, displaced along the vertical direction by Δl, where l is the length of the loop antenna, as before. For the same reason as in the case of the coaxial probe, it is advantageous to have a loop 32 of relatively long shape so that a shielding 31 does not affect the signal detected by the loop 32 and also does not affect performance of the DUT. Subtracting two sets of data corresponding to the two positions of the antenna makes the measurement in a sense equivalent to the small loop identified in FIG. 11 by the numeral 33.

To carry out the invention, it is necessary, as has been explained to site the antenna at predetermined distances from the DUT. The closest distance must be sufficiently large to avoid mutual coupling between the antenna and the DUT and, at the same time, it must be sufficiently close to the OUT to obtain the necessary signal with required resolution. An accurate mechanism has to be employed to control the distance at which the antenna is cited relative to the DUT. As has been mentioned already, one of the most attractive ways of carrying out this task is to use some form of device based on a quartz crystal oscillator such as a tuning fork and monitoring the interaction forces between the probe and the surface. These obviously operate much closer to the surface of the topography they are scanning, than the microwave field antenna operates. Thus, what is required first is to obtain an accurate measurement of where exactly the particular surface of the DUT is and then to move the antenna to the predetermined distance. A quartz crystal oscillator is particularly effective and forms the basis of the devices of the present invention, however, they are employed in the way that is not similar to those in common use.

The topography sensing device comprises the tuning fork oscillator in self-excitation mode where its piezoelectric property is used for both the excitation of mechanical vibrations and detection of the amplitude of these oscillations.

The present invention separates excitation and response signals at the tuning fork electrodes. The separation is based on the fact that under certain conditions the mechanical oscillations and therefore electrical responses are shifted relative to the excitation forces and the corresponding excitation electric signal by 90 degrees, referred hereinafter as the signal orthogonality. This 90° phase shift occurs exactly at the resonance frequency. Those signals can be represented either by voltages at fork electrodes forming a topography probe or by currents flowing through the crystal. Due to the relatively high impedance of the quartz crystal, it is convenient to present the signals by the currents, namely by the excitation current Iₑ and by the additional response current I_{f} induced by mechanical vibrations of the tuning fork. The signal orthogonality allows a phase-sensitive detection of the component corresponding to the mechanical vibrations only and the suppression of the excitation signal. After the conversion of the currents to voltages this detection is performed using a Lock-In Amplifier (LiA) such as SR830 (Stanford Research) where the signals are demodulated relative to a reference signal provided by an excitation generator. The phase of either this reference or measured signals has to be adjusted in a phase shifter to assure a 90 degrees phase shift between the reference and probe excitation signals. This phase shift allows nearly complete suppression of such an out-of-phase signal. The functional component Iₜ, corresponding to mechanical vibrations, is in-phase with the reference signal and it is fully demodulated. The amplitude of the output signal U₀ after lock-in detection can be written in the form

$$\begin{matrix}{U}_{0} = \frac{R}{τ} {\int }_{⪡ - τ}^{t = 0} [ {I}_{e} sin ( ω t ) + {I}_{f} cos ( ω t ) ] cos ( ω t ) {ⅇ}^{t / τ} ⅆ t \\ ≅ \frac{R}{\sqrt{2}} {I}_{f}\end{matrix} \qquad ( 7 )$$

where τ is the time constant of the lock-in demodulation and R is the conversion constant of the current-to-voltage I/V converter. Here the time of the measurement is designated at t=0. The formula shows that the output is proportional to the functional component I_{f} only and it can be used in the feedback to control the separation between the tip and the DUT. Therefore both the excitation signal and the input for the response measurement are connected to the same electrodes of the tuning fork resonator and the use of an external piezo element is not required. Thus, a tuning fork with a probe attached to it functions not only for the detection of the oscillations but also as an active dithering element.

Referring to FIG. 12, there is illustrated a topography sensing system, again indicated generally by the reference numeral 15. In FIG. 12, components similar to those described with reference to previous drawings, are identified by the same reference numerals. In this embodiment, the tuning fork or quartz crystal oscillator 16 is mounted on a ceramic holder 30. The tuning fork in this particular embodiment was a standard watch quartz crystal (such as an AEL and Euroquartz, supplied, for example, by Radionics Part No. 304-447) removed from its protective encapsulation and attached to the holder by an adhesive (EpoTek 77). By mounting an additional mass of the topography probe 17 on the tuning fork 16, the resonance frequency of the fork drops from its standard value 32768 Hz to one in a range of 25-30 kHz, depending on the particular mass of the probe attached thereto. In one embodiment, the probe was produced from a glass optical fibre. The probe 17 had a sharp apex 37 formed using a puling machine with CO₂ laser heating. All of these components form a quartz crystal oscillator assembly delineated by the interrupted lines and identified by the reference numeral 35.

The circuitry of the topography sensing system 15 comprises, as well as the lock-in amplifier 19 and generator 18, described already, a high impedance signal coupling element 40, formed by a capacitor of about 520 pF or a resistor of 0.2-1 MΩ. The generator also feeds a phase shifter 41 to provide a reference signal, identified by the reference numeral 44, to the lock-in amplifier 19. The lock-in amplifier 19 also collects a signal, identified by the reference numeral 43, from the tuning fork 16.

In use, the probe 17 is excited so that the tip 37 is also excited at resonance frequency to amplitudes in the range of 10-200 nm. The representative experimental result on interaction forces between the tip 36 and the DUT 2 are illustrated in FIG. 14. The dependence of the amplitude on the separation is used in the feedback to keep the separation constant. The feedback comprises the piezo actuator 21, as illustrated in FIG. 1, which positions the probe 17 in a vertical direction to keep the separation in the middle of the interaction range, corresponding to an oscillation amplitude equal approximately to half that of the oscillation of the tip 36, i.e. without the presence of the DUT 2. As has been explained already, the amplifier 20, as illustrated in FIG. 1, is used for transformation of the response signal to the piezo positioning voltage.

It will be appreciated that there are many ways of achieving signal coupling to the quartz fork and phase-sensitive signal demodulation. Two practical ways are described, however, many other ways will be readily apparent to those skilled in the art. The first more general, use a high impedance element 40 for coupling of the excitation signal from a generator 18 to a tuning fork 16. As the correct choice of the signal phase is very important for maximising suppression of the excitation signal from the generator, incorporation of either a digital or analogue LIA with a high performance phase shifter is usually required. Both analogue or digital LIA can be used. The signal from the excitation generator is also used as the reference signal 44 for the LIA 19.

Referring now to FIG. 13, there is illustrated an alternative construction of a topography sensing system, again indicated generally by the reference numeral 15. Again, parts and components similar to those described with reference to the previous drawings, are identified by the same reference numerals. In this embodiment, the tuning fork 16 is inserted between the generator 18 and an IV converter 48 delineated by interrupted lines and comprising an operational amplifier 46 and a resistor 47. In this embodiment, the generator 18 feeds the reference input 44 of the lock-in amplifier 19 directly and the signal 43 is fed via the IV converter 48.

Since the tuning fork, which is a quartz crystal, represents for excitation signal a small capacitor Cₜ (with capacitance of 3-20 pF), the circuit consisting of elements 16, 46, 47 represents an electronic differentiator with integration factor determined by the capacitance Cₜ of the tuning fork 16 and resistance R of element 47. This excitation results in the output signal of magnitude U₈=2πfRC_{f} and is always shifted in phase by 90° relative to the phase of signal from the generator 18. Therefore it is suppressed by phase-sensitive detection of the lock-in amplifier 19. The functional component, namely, the response Iₜ, resulting from mechanical oscillations, is phase shifted relative to that of the excitation by an additional 90 degrees at the resonance frequency. Its resulting voltage U_{f}=−RI_{f} has the phase opposite to that of the generator 18 voltage and it is fully demodulated by the lock-in amplifier 19. As the phase shift of the electronic differentiator provided by the circuit is constant for all frequencies, the excitation source generator 18 can be easily tuned to the resonance of the tuning fork 16 without any need for further phase adjustment.

An additional advantage of this circuit is that the input, identified by the reference numeral 49, to the I/V converter 48 represents a virtual ground. It has virtually zero impedance relative to the ground point and brings minimal uncertainties to the phase of the signals. Otherwise, the phase of the signals would be influenced by load impedance of the signal measurement system because of small capacitance and high impedance of the tuning fork 16. The I/V converter 48 is plugged very close to the tuning fork 16 and functions simultaneously as a signal conditioner whose low impedance output at 43 can be matched to the impedance of a standard transmission line. No additional preamplifier (such as the one described in EP patent Specification No. 0864864) is required. The suppression of the generator 18 signal by the phase-sensitive detection is typically more than 3 orders of magnitude, resulting in a residual excitation signal of level 10-100 times smaller than that of the functional component, I.e. the response signal of mechanical oscillations. Such a ratio between the signals is sufficient for incorporation of the circuit in the feedback of distance control system for operation with the present invention.

The distance control system based on the self-excitation of the tuning fork according to the present invention has a number of advantages over the state-of-the-art system utilising a tuning fork and a dithering piezo. Both systems have similar sensitivities and comparable response times. However, the system based on the self-excitation has a simpler design, as no external dithering piezo is required. Also the system with the self-excitation is highly simple to adjust. There are no requirements of phase adjustment of the detected signal, as the electric excitation signal on the quartz fork electrodes is always in phase with the excitation forces and out of phase (shifted by 90°) the mechanical oscillations and response signal. In the state-of-the-art approach the phase shift, caused by the particular mechanical contact of the external dithering piezo and transfer of the mechanical vibrations from that piezo to the tuning fork is always present and the phase of the detected signal has to be tuned. These advantages result in an increase in the system's reliability and robustness.

When compared with the time gating technique, described above, the present system has also a number of advantages. It has a simpler electronic circuit, and does not require a time-gating modulation and complex adjustment of the frequency of the oscillator. According to the invention the circuit itself acts as a signal conditioner for the response signal thus resulting in a much better match in the input impedance. There is no residual modulation of the amplitude of the tip oscillation by the time-gating signal. These advantages result in a shorter response time and thus a faster scanning capability.

To maintain the separation between the antenna and the surface the following procedure is employed. First, the surface of the DUT is scanned using a topography probe such as described above. The topography is recorded. Then the topography probe is replaced for the antenna. In one embodiment, the topography probe and antenna are each attached to a single XYZ translation stage device which is computer controlled. First, the topography probe is brought in focus of a long focal distance microscope. Then the computer controlled mechanical translation stage removes the topography probe from the focus and brings the antenna to the same focal point of the microscope. The computer records the position offset as accomplished by the XYZ stage between the two positions. This offset is then added to bring the antenna out of the direct proximity (1-50 nm) of the surface to avoid direct capacitive coupling between the DUT and the antenna. Additionally the Z-axis offset is added to increase the separation between the antenna and the surface from the value of 1-30 nm for the shear force-based topography probe to the value of e.g. 5 to 100 μm as required for the microwave signal acquisition.

The present invention may be used for scanning large size areas. Typically the size of the DUT could be in the range of some 10-200 mm. One can readily find precision motorised translation stages that are capable of proving accurate lateral displacement in this range along the X and Y axes. Indeed sub-micrometer precision for the lateral displacement is more than adequate. However, the situation with the height control, I.e. movement along the Z-axis normal to the DUT surface is much more complex. The problem is that one needs to have a large dynamic range of Z-displacement, typically in the range of 10 mm or more and simultaneously, high resolution, down to some 1 nm. The high resolution is required as the probe height control is based on SF or AF interaction that is only active in the nanometer height range. Therefore, the conventional positioning tools used with the scanning probe (SF, AF) microscopes are inadequate for the purpose of the Z-axis displacement. Typically piezo tubes or piezo stacks are used. They are capable of providing the required resolution of the displacement but their dynamic range is limited to a fraction of a millimetre. A hybrid solution utilising both a piezo stack and a motorised translation stage is envisaged. In use, during the topography scan the motorised stage is maintained at such a position that the piezo stack is kept in close to the middle of its dynamic range. For example, if the piezo stack is displaced from the middle of its dynamic range, by more than +/−25%, the motorized stage performs adjustment and moves the probe so that piezo stack is placed again in the middle of its range. In this way the feedback system can operate smoothly as piezo stack with fine position resolution and not the motorised stage is involved continuously in the z-position adjustment. We have used long-range piezo-actuator (90 μm Physik Instrumente P-841.60) in combination with procision motorised stage PI M-406.DG, which allows relatively fast acquisition of the topography of measured DUT.

It is impossible to specify any particular separation between the DUT and the antenna apex, as the correct distance depends on the geometry or size of the signal lines on the DUT. In general, it has been found that the separation should be greater than roughly half of the diameter of the protruding portion of the antenna. However, in certain circumstances, to obtain better resolution, it may be decided to make it somewhat smaller. Since the correct separation depends on the particular DUT, it will always be a matter of experimentation and of the requirements of the particular test before the optimum separation can be provided.

While in the embodiments described above, a topography sensing system, based on measuring shear force when the to is dithered parallel to the DUT surface, was described, it will be appreciated that, equally well, a probe oscillating perpendicular to the surface can be used.

It will be appreciated that, as mentioned already, when assessing the operation of DUTs during the development phase, a large number of measurements will be taken and further, considerable accuracy in placing the antenna must be achieved. However, during the production phase, there will be much less measurements and further, these measurements must be carried out much more quickly. Accordingly, what will be done, to speed up the operation, is to record the test position relative to a datum point of a fixture for reception of the DUT and this test position will then be used for subsequent similar DUTs placed on the fixture. In this way, the antenna will not have to be accurately positioned each time using the topography probe. It is also envisaged that the test position from a number of similar DUTs could be recorded, averaged and used to provide the test position for subsequent similar DUTs.

Further, it will be envisaged that when a plurality of DUTs have been determined to function correctly in practice, the measurements will be carried out on one or more test points and the resultant measurements recorded as acceptable measurements for a subsequent DUT measured at these test points. Obviously, in this way, the speed of measurement during production will be greatly enhanced.

In some cases, it is necessary to determine the height of the surface of DUT 2 at each point where electromagnetic measurement is to be performed prior to such measurement. In other words, it may not be sufficient to rely on topographic information obtained for one or several DUTs to use it for placement of the antenna to testing points of similar DUTs. This is due to position uncertainties caused by DUT production tolerances, errors and uncertainties during mounting of a DUT in the test fixture or simply due to deformation of a DUT. In such a case the elevation of the surface has to be determined for each individual DUT to allow placing the antenna precisely at the specified height above the DUT for each position. Although this elevation can be measured by shear-force (or AFM) topography sensing system as described above, the time of testing for a single point could become unacceptably long. The reason is that the speed at which the topography probe can be approached to the surface is limited by the response time of the feedback loop. In the topography probe approaches a surface too fast, it may crash into the surface before the feedback response to the shear-force contact. The typical approach time for a singlo point is 15-40s, which may not be acceptable if a large number of DUTs are tested during the production phase. In such a situation an alternative fast topography sensing system is required.

Referring to FIG. 15, there is provided an elevation sensing system, indicated generally by numeral 60, comprising a probe in the form of a stiff rod 61 having an apex 72. The rod 61 can freely move inside a holder in the form of a guiding tube 62. In a typical embodiment the guiding tube 62 is a glass tube with an internal diameter in the range 70-200 μm and the rod 61 is a glass rod with a diameter in the range 50-180 μm. An upper part of the rod is coated with a metal forming a sleeve 67 so that is not transparent to the light. A fixing ring 69 is mounted below the sleeve 67 to form a stop and thus define the lowest position of the rod 61. In this position, the rod 61 projects a distance Sₐ out of the guiding tube 62. Alternatively, an opaque screen with a size of some 0.5×0.5 mm is glued on the top of the rod. Means to record displacement of the rod 61 is provided by a position sending device. In this embodiment, the position is determined by an opto-coupler, comprising a light-emitting diode 63 (such as supplied by Farnell under Part No. SE5470), a photo-detector 64 (such as supplied by Farnell under Part No. L14F1) and optical lenses 65 and 66 to focus a light beam to a threshold position 68 and to the sensitive area of the photo-detector 64. During the measurement of the elevation of the DUT surface, the system 60, mounted on a vertical (Z) motorised positioning stage such as the vertical (Z) motoristed position stage 22, described above. Using the position stage 22, the rod 61 is moved towards the DUT 2. As the rod 61 approaches the DUT 2, continuous monitoring of the signal detector by opto-coupler is carried out. Before contact is made between the rod 61 and the DUT 2, the rod apex 72 is located in its lowest rest position, determined by fixing ring 69. After the contact with the DUT 2 the rod 61 is pushed upwards and at some moment determined by the threshold position 68 of its upper end, it disrupts the path of the light beam, detected by photo-detector 64. At that moment the position of the vertical (Z) motorised positioning stage 22 is recorded and stored in a computer, such as the computer 24 described above. The movement of the stages is then decelerated within a short path that does not exceed the distance Sₐ and the elevation-sensing system 60 is withdrawn by a servo-mechanical device. The antenna is then displaced by offsets ΔX, ΔY, ΔZ+dz to position its apex at specified distance dz above the inspection point of the DUT. The offset values ΔX, ΔY, ΔZ represent the distance between the antenna apex and the lower end, I.e. the apex (72) of the rod 61 for its threshold position 68 when the sleeve 67 forming is upper end disrupts the light beam of the opto-coupler. These values are determined once before the measurement process using a reference sample (usually a static reference tip) in a procedure similar to that decribed above for replacement of shear-force topography probe for the field antenna.

This threshold position 68 would generally be marginally above the probe, I.e. the rod 61, but could equally be sited some distance above it once the distance is known, all that is required is to be able to record the position of the holder 62 above the DUT. The elevation sensing system, since it incorporates the vertical (Z) motorised positioning stage, also mounts the antenna.

In the specification the terms “comprise, comprises, comprised and comprising” or any variation thereof and the terms “include, includes, included and including” or any variation thereof are considered to be totally interchangeable and they should all be afforded the widest possible interpretation and vice versa.

The invention is not limited to the embodiment hereinbefore described, but may be varied in both construction and detail within the scope of the appended claims.

1. A method of assessing the operation of a device under test (DUT) at high and microwave frequencies comprising using an antenna terminating in a tip or apex to acquire microwave electromagnetic field measurements in a near field region of a test point of the DUT comprising the steps of:—
siting the antenna in a test position with its tip at a predetermined distance and at a predetermined inclination to the test point;
energising the DUT; and
measuring and recording a microwave property of the DUT.

2. A method as claimed in claim 1, comprising the additional steps of:—
displacing the antenna along its axis to site the antenna at another test position a predetermined distance and at substantially the same inclination to the test point;
measuring and recording the microwave property; and
calculating and recording the difference in the microwave properties to provide information about the operation of the DUT.

3. A method as claimed in claim 2, in which the antenna is displaced a distance between 1 μm and 50 μm.

4. A method as claimed in claim 1, in which the inclination of the antenna is substantially orthogonal to the DUT.

5. A method as claimed in claim 1, in which the antenna is sited at an inclination to the vertical and the method comprises the additional steps of:—
rotating the antenna about its apex by a predetermined rotation angle, while maintaining its inclination to the vertical;
measuring and recording the microwave property;
calculating and recording the difference in the microwave properties to provide information about the operation of the DUT.

6. A method as claimed in claim 5, in which the predetermined rotation angle is substantially 180°.

7. A method as claimed in claim 5, in which the antenna is rotated at rotation angles of substantially 120° and 240° to obtain three sets of measurements.

8. A method as claimed in claim 5, in which the inclination to the vertical is substantially 45°.

9. A method as claimed in claim 1, in which the sensitivity of measurement of the electrical field intensity at a particular frequency is defined by
$$S = \frac{Δ U}{{E}_{l} Δ l}$$
where:
ΔU is the voltage difference of antenna signal measured for two positions of the antenna displaced along antenna axis;
Δl is the displacement of the test positions;
Eₗ is the component of the electrical field intensity of the microwave field parallel to the antenna axis; and
S is a sensitivity constant
and in which
the sensitivity constant (S) is determined by a calibration measurement in a well defined field standard and is subsequently used to determine the real value of the electrical field intensity of a DUT during a test.

10. A method as claimed in claim 1, in which the microwave property of the DUT is one of the amplitude, phase or frequency of the voltage detected by the antenna.

11. A method as claimed in claim 1, in which the test position is chosen to minimise the capacitive and inductive couplings between the antenna and the DUT while providing a sufficiently strong signal.

12. A method as claimed in claim 11, in which the test position is at least spaced-apart from the DUT by a distance greater than the widest lineal dimension of the tip of the antenna facing the DUT.

13. A method as claimed in claim 11, in which the separation between the tip of the antenna and the test point of the DUT is between 1 μm and 100 μm.

14. A method as claimed in claim 1, in which the frequency range of operation is between 50 MHz and 50 GHz.

15. A method as claimed in claim 1, in which the frequency range of operation is between 300 MHz and 30 GHz.

16. A method as claimed in claim 1, in which the siting of the antenna comprises:—
moving a topography probe, attached to a quartz crystal oscillator to a probe position adjacent the DUT;
fixing and recording the probe position;
measuring the offset distance between the probe and the antenna apex using a separate offset distance measuring device; and
positioning the antenna apex above the same point of the DUT by taking into account the offset distance and displacing the antenna by an additional distance along the antenna axis.

17. A method as claimed in claim 16, in which the topography sensing system comprises an excitation generator to operate at the resonance frequency of the probe and means to extract the oscillation response signal of the probe from that of the excitation signal based on the orthogonality of the phases of those signals and hence a measure of the distance of the probe from the DUT.

18. A method as claimed in claim 16, in which in order to measure the offset distance the topography probe is brought into a focus point of a long focal length microscope and the antenna are brought to the same focus point to measure the offset between the positions of the probes.

19. A method as claimed in claim 16, in which the test position is recorded relative to a datum point of a fixture for reception of the DUT and this test position is used for subsequent similar DUTs placed on the fixture.

20. A method as claimed in claim 19, in which the test position for a number of similar DUTs is recorded, averaged and used to provide the test position for subsequent similar DUTs.

21. A method as claimed in claim 1, in which a plurality of DUTs which have been determined to function correctly in practice are measured at one or more test points and the resultant measurements recorded as acceptable measurements for subsequent DUTs measured at these test points.

22. An antenna (3) for use in the method of claim 1, comprising a coaxial shielding (7) and a protruding conductor (8) therefrom in which the length by which the conductor protrudes from its shielding (7) substantially exceeds the greatest lineal dimension (D) of the shielding (7) adjacent the conductor (8) to isolate the effects of the shielding (7) from the DUT (2).

23. An antenna (3) as claimed in claim 22, in which the antenna is a coaxial antenna (3) and in which the length (l) by which the conductor (8) protrudes exceeds, by at least a factor of two, the external diameter (D) of its coaxial shielding (7) and by at least the same factor, the smallest dimension (w) of the feature at the DUT that needs to be resolved.

24. An antenna (3) as claimed in claim 23, in which the factor is at least three.

25. A topography sensing system (15) for use in the method of claim 1 comprising:—
a quartz crystal oscillator (16);
a topography probe (17) connected to the oscillator (16);
an excitation generator (18) having means to operate at the resonance frequency of the oscillator (16) with the probe (17); and
means to shift the phase of the oscillation frequency of the probe (17) from that of the oscillation signal and to extract the oscillation signal ais a measure of the distance between the probe (17) and the topography.

26. A topography sensing system (60) for determining the vertical height above a DUT in the method as claimed in claim 1 comprising:—
a holder (62);
control means for moving the holder vertically with respect to the topography;
a probe (61) being supported in the holder (62) in a rest position and freely movable upwards within the holder (62) on the tip (72) of the probe (61) contacting portion of the DUT (2);
means to record displacement of the probe (61) on contact being made to measure the distance of the holder (62) from the portion of the DUT (2) with which contact was made.

27. A sensing system (60) as claimed in claim 26, in which the holder (62) comprises a bored tube and the probe (61) is a stiff rod mounted within the tube.
